(19) United States
(12) Patent Application Publication
(10) Pub. No.: US 2008/0153253 A1
(43) Pub. Date: Jun. 26, 2008

(54) Chemical mechanical polishing process and method of fabricating semiconductor device using the same

(75) Inventors: Il-young Yoon, Hwaseong-si (KR); Jae-ouk Choo, Yongin-si (KR); Nam-jin Jung, Hwaseong-si (KR); Dong-hun Kim, Suwon-si (KR); Han-woo Lee, Suwon-si (KR); Gyu-nam Kim, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/003,301

(22) Filed: Dec. 21, 2007

(30) Foreign Application Priority Data
Dec. 22, 2006 (KR) 10-2006-0133028

(51) Int. Cl. H01L 21/762; B24B 1/00

(52) U.S. Cl. 438/424; 451/36; 257/E21.546

(57) ABSTRACT

A chemical mechanical polishing process and a method of fabricating a semiconductor device using the same are provided. The chemical mechanical polishing process includes applying a polishing activation solution with a reduced surface energy, wherein the polishing activation solution includes a surfactant; and polishing the object using the polishing activation solution. The method of fabrication includes forming a mask layer pattern on a semiconductor substrate, etching the substrate using the mask layer pattern as an etching mask, forming an insulating layer over a trench, and performing the chemical mechanical polishing above, wherein the object to be polished is the insulating layer.

### PRIORITY STATEMENT

This application claims the benefit of priority under 35 U.S.C. §119 from Korean Patent Application No. 10-2006-0133028 filed on Dec. 22, 2006 in the Korean Intellectual Property Office, the disclosure of which is incorporated herein by reference in its entirety.

### BACKGROUND

1. Field

Example embodiments relate to a chemical mechanical polishing process and a method of fabricating a semiconductor device using the same. Other example embodiments relate to a chemical mechanical polishing process using a polishing pad including an abrasive and a method of fabricating a semiconductor device using the chemical mechanical polishing process.

2. Description of the Related Art

As more highly-integrated and multi-layered semiconductor devices are formed, irregular prominences and/or depressions are likely to occur during the fabrication of semiconductor devices. A process for removing the prominences and/or depressions is referred to as planarization. Planarization is a critical process for forming reliable and highly integrated semiconductor devices. Chemical mechanical polishing (CMP) is a frequently used planarization process. Despite costs, the use of CMP processes is relied upon for many applications in order to form more reliable devices.

A conventional CMP process includes pressing an object to be polished on a polishing pad using a slurry having polishing particles and rotating the resulting structure. The slurry may chemically react with the object to be polished. The slurry may be physically rubbed with the object to be polished to perform the chemical mechanical polishing. The slurry may be supplied from a slurry supplying device that is provided by means of an external device or through the polishing pad.

The slurry may not be uniformly supplied to an entire region. Because surface energy of the slurry or deionized water (that assists the chemical reaction of the slurry) is high, it may not be easy to uniformly distribute the slurry or the deionized water between the polishing pad and the object to be polished, which come into close contact with each other. If the slurry or the deionized water is not uniformly supplied to different regions, a polishing ratio of the object to be polished varies for each region, reducing planarization characteristics.

### SUMMARY

Example embodiments relate to a chemical mechanical polishing process using a polishing pad including an abrasive and a method of fabricating a semiconductor device using the chemical mechanical polishing process.

Example embodiments provide a chemical mechanical polishing process with increased planarization characteristics and a method of fabricating a semiconductor device using the same.

According to example embodiments, there is provided a chemical mechanical polishing process that includes applying a polishing activation solution with a reduced surface energy to an object to be polished and polishing the object using a polishing activation solution. The polishing activation solution may include a surfactant.

According to example embodiments, there is provided a method of fabricating a semiconductor device. The method includes forming a mask layer pattern on a semiconductor substrate, etching the semiconductor substrate using the mask layer pattern as an etching mask to form a trench, forming an insulating layer for isolating elements over (or filling) the trench, and chemical mechanical polishing of the insulating layer isolating elements using a polishing activation solution having a reduced surface energy due to the addition of a surfactant.

### BRIEF DESCRIPTION OF THE DRAWINGS

Example embodiments will be more clearly understood from the following detailed description taken in conjunction with the accompanying drawings. FIGS. 1-12B represent non-limiting, example embodiments as described herein.

FIG. 1 is a flow chart illustrating a chemical mechanical polishing process according to example embodiments;

FIG. 2 is a diagram illustrating a sectional view of a chemical mechanical polishing apparatus according to example embodiments;

FIG. 3 is a perspective view of an enlarged portion of a polishing pad applied to the chemical mechanical polishing apparatus of FIG. 2;

FIGS. 4A to 4C are diagrams illustrating sectional views of the polishing pads according to example embodiments;

FIG. 5 is a diagram illustrating a sectional view of a chemical mechanical polishing apparatus according to example embodiments;

FIGS. 6 to 10 are diagrams illustrating sectional views of a method of fabricating a semiconductor device according to example embodiments;

FIG. 11 is a graph illustrating surface energy of a polishing activation solution as a function of an amount of surfactant according to example embodiments; and

FIGS. 12A and 12B are graphs illustrating polishing rates before and after the addition of a surfactant.

### DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

A chemical mechanical polishing process according to example embodiments will be described with reference to the accompanying drawings hereinafter.

Example embodiments relate to a chemical mechanical polishing process using a polishing pad including an abrasive and a method of fabricating a semiconductor device using the chemical mechanical polishing process.

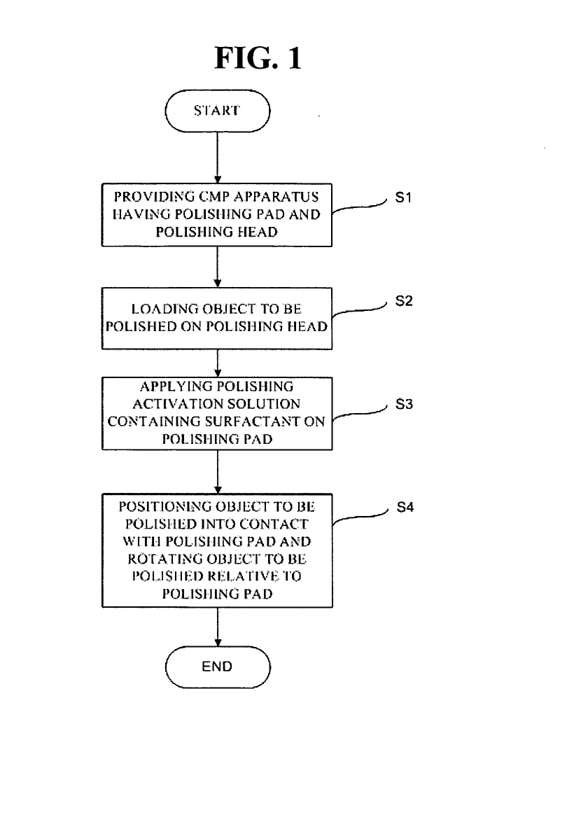

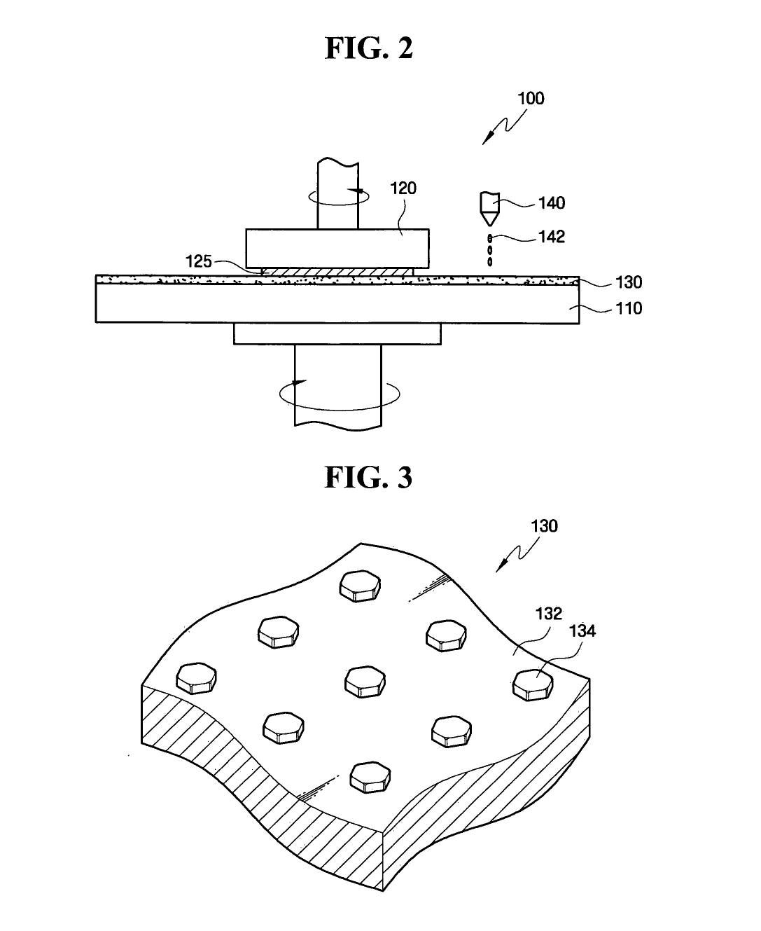

FIG. 1 is a flow chart illustrating the chemical mechanical polishing process according to example embodiments. FIG. 2 is a diagram illustrating a sectional view of a chemical mechanical polishing apparatus according to example embodiments.

Referring to FIG. 1, a chemical mechanical polishing (CMP) apparatus including a polishing pad and a polishing head is provided S1.

Referring to FIG. 2, a CMP apparatus 100 according to example embodiments includes a polishing table 110, a polishing pad 130 disposed (or formed) on the polishing table 110 and a polishing head 120 on which an object to be polished 125 is loaded. Because at least one of the polishing table 110 and the polishing head 120 rotates, the polishing table may rotate relative to the polishing head.

The polishing head 120 may include a pressing device (not shown) that presses the polishing head 120 downward. In order to compensate for the difference in polishing rates according to the distance between the center of the polishing head 120 and a desired position of the object to be polished 125, the pressing device of the polishing head 120 may apply different pressures to different regions of the object to the polished 125.

Because the object to be polished 125 may rotate while being supported by the polishing head 120 and the object to be polished 125 may be disposed (or positioned) on a lower surface of the polishing head 120, a fixing device (not shown) may be provided on the polishing head 120 to more safely load the object to be polished 125. Examples of the fixing device may include a vacuum adsorption device and a fastening protrusion. However, any fixing device known in the art may be used.

The polishing pad 130 may be disposed (or positioned) on the polishing table 110 and may move along with the polishing table 110. The polishing pad 130 may be made of a polymer (e.g., PET (PolyEthylene Terephthalates), polycarbonates or polyurethanes). The polishing pad 130 may be attached to the polishing table 110 by an adhesive. The attached polishing pad 130 may be subjected to conditioning or replaced with another polishing pad 130, if the polishing pad is worn, after a desired amount of time has elapsed.

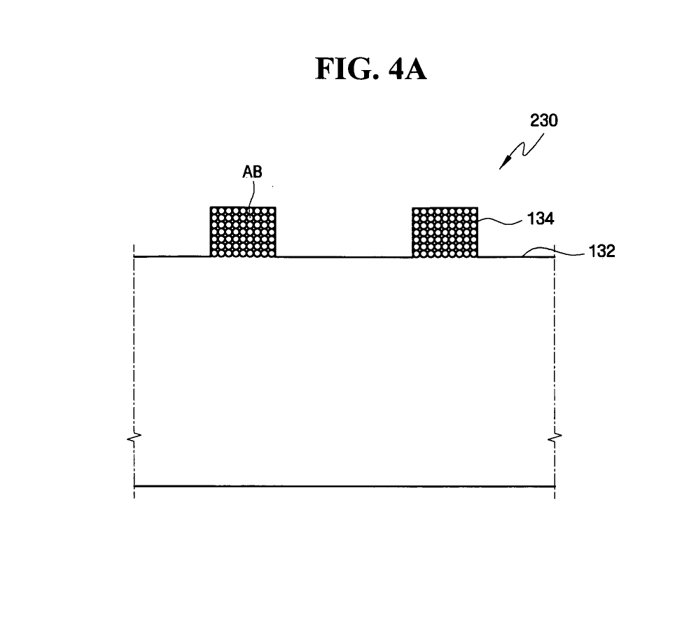

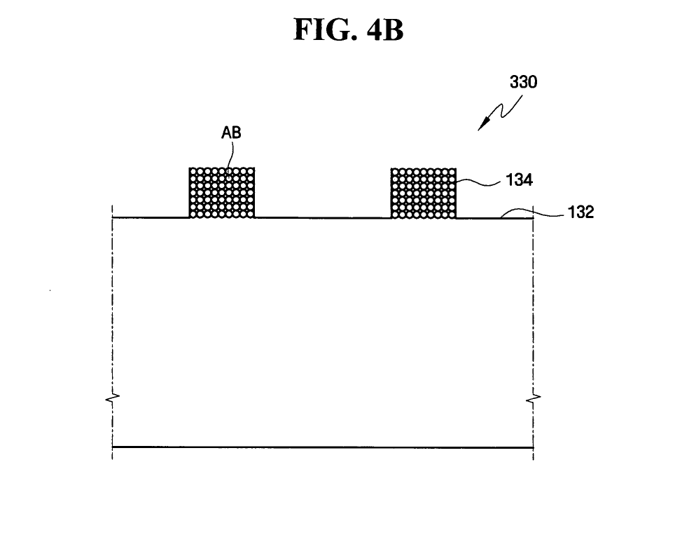

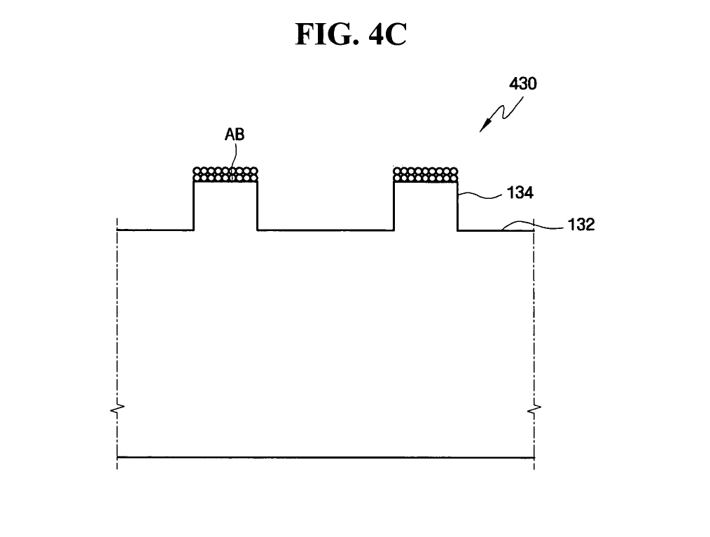

An abrasive and/or a protrusion portion may be provided on the polishing pad 130 as an abrasion activation device. A detailed description thereof will be given with reference to FIGS. 3 to 4C.

FIG. 3 is a perspective view of an enlarged portion of a polishing pad used in the chemical mechanical polishing apparatus of FIG. 2. FIGS. 4A to 4C are sectional views of polishing pads according to example embodiments.

Referring to FIG. 3, the polishing pad 130 may include a plurality of protrusion portions 134 that protrudes from an upper surface 132 of the polishing pad 130. A remaining portion of the upper surface 132 of the polishing pad 130 (other than the protrusion portions 134) may be substantially flat.

The protrusion portion 134 may have the hexagon pillar shape. The protrusion portion may have various shapes (e.g., a rectangular pillar, a square pillar, a cylinder and a cylindroid). Because the protrusion portion 134 is closest to the object to be polished 125 loaded on the polishing head 120, the protrusion portion 134 may have any shape as long as the upper surface of the protrusion portion 134 is flat. The plurality of protrusion portions 134 may be arranged at regular (or systematic) intervals on the upper surface 132 of the polishing pad 130 to perform the more uniform polishing.

The polishing pad 130 may include an abrasive (AB). The abrasive (AB) may include metal oxides (e.g., ceria, silica, alumina, titania, zirconia and germania).

If the abrasive (AB) is already mixed with the polishing pad 130, it is unnecessary to supply the abrasive (AB) using an additional device. As such, the structure of the CMP apparatus 100 may be simplified.

Because polishing efficiency of the abrasive (AB) is increased, the amount of abrasive (AB) exhausted to the outside while being not used to perform the polishing may substantially decrease contrary to the abrasive (AB) is supplied using the additional device. The consumption of costly abrasive (AB) and/or the treatment cost of the metal oxide that causes severe environmental pollution may decrease.

If the polishing pad 130 includes the plurality of protrusion portions 134, the abrasive (AB) may be disposed (or positioned) on the protrusion portions 134. If the abrasive (AB) is disposed on the protrusion portion 134, it is possible to increase the polishing efficiency because the protruding protrusion portion 134 of the polishing pad 130 functions as the main polishing surface.

FIGS. 4A-4C are diagrams illustrating sectional views of polishing pads according to example embodiments.

Referring to FIG. 4A, the abrasive (AB) may be buried (or filled) in the protrusion portion 134 of the polishing pad 230.

Referring to FIG. 4B, the abrasive (AB) may be buried (or filled) in the protrusion portion 134 of the polishing pad 330 but exposed if a portion of the polishing pad 330 that forms the surface of the protrusion portion 134 is removed due to factors (e.g., abrasion or infiltration in the surface of the protrusion portion 134).

Referring to FIG. 4C, the abrasive (AB) may be attached to the surface of the protrusion portion 134 of the polishing pad 430.

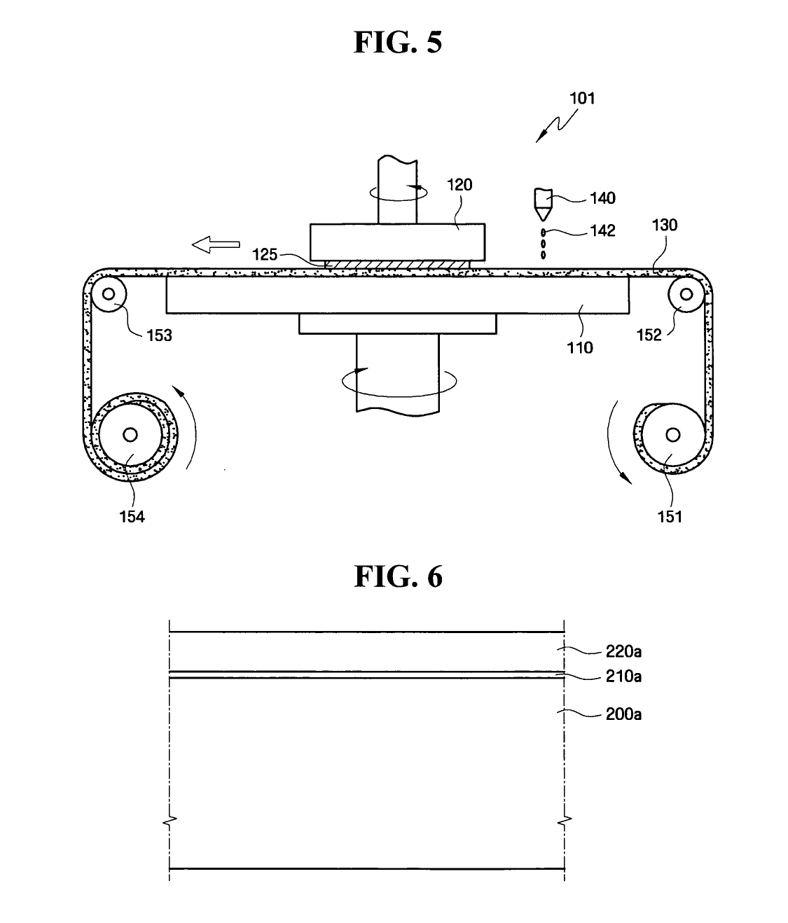

FIG. 5 is a diagram illustrating a sectional view of a chemical mechanical polishing apparatus according to example embodiments.

Referring to FIG. 5, in a CMP apparatus 101 according to example embodiments, the polishing pad 130 may be disposed (or positioned) on the polishing table 110 but not attached to the upper surface of the polishing table 110. The CMP apparatus 101 may be provided with rotating rollers 151, 152, 153, 154. The polishing pad 130 may be wound around the rotating rollers 151 and 154 such that the polishing pad 130 rotates on the polishing table 110. A unused (or different) region of the polishing pad 130 is provided on the polishing table 110 by rotating the rotating rollers 151-154. As such, it is unnecessary to stop the CMP apparatus 101 to replace a used (or worn) region of the polishing pad 130 with a new pad. If the polishing table 110 rotates, the polishing pad 130 and the rotating rollers 151, 152, 153, 154 rotate along with the polishing table 110.

The above-mentioned CMP apparatuses 100 and 101 are set forth to only illustrate example embodiments. However, the CMP method according to example embodiments may be performed using CMP apparatuses different from the CMP apparatuses 100 and 101.

As shown in FIG. 1, the object to be polished 125 may be loaded on the polishing head 120 S2. The loading of the object to be polished 125 may be performed using the fixing device (e.g., the vacuum adsorption device or the fastening protrusion that is provided in the polishing head 120).

A polishing activation solution 142 including a surfactant may be applied to the upper surface of the polishing pad 130 S3. Application of the polishing activation solution may be performed using a solution application device 140. The polishing activation solution 142 activates the polishing using the abrasive. The polishing activation solution 142 may include deionized water and/or an additive that is dissolved in deionized water. The additive may be a substance that increases the polishing selectivity and the polishing efficiency (e.g., KOH and L-proline).

The surface energy of the polishing activation solution 142 may be low in order to ensure effective wetting ability. The surface energy of the polishing activation solution 142 may be the same as or smaller than the polishing pad 130. The wetting ability relates to the uniform distribution of the polishing activation solution 142. Because the ability to spread the polishing activation solution 142 on the polishing pad 130 is easier as the wetting ability increases, the abrasive in the polishing pad 130 is more uniformly activated to increase uniformity of the polishing.

If PET (PolyEthylene Terephthalate), polycarbonates or polyurethanes are used for the polishing pad 130, the surface energy of the polishing pad 130 is in the range of about 41 dyne/cm to about 46 dyne/cm. The polishing activation solution 142 that includes KOH or L-proline has a surface energy of about 70 dyne/cm. The surfactant is added to decrease the surface energy of the polishing activation solution.

The surfactant decreases the surface energy of the polishing activation solution 142 and increases the polishing selectivity and the polishing efficiency. Examples of the surfactant include a polymeric anionic fluorinated surfactant (e.g., a perfluorobutane compound, a hydrocarbon surfactant) and a non-fluorinated surfactant (e.g., silicone polyethers, sulfosuccinates, aliphatic alcohols and propylated aromatics).

The amount of surfactant added varies on the type of surfactant used. If the surfactant is added in an amount of about 0.0001 wt % to about 1 wt % based on the total weight of the polishing activation solution 142, the surface energy of the polishing activation solution 142 may be about 10 dyne/cm to about 40 dyne/cm. Because the surface energy of the polishing activation solution 142 may be smaller than that of the polishing pad 130, spreading the polishing activation solution 142 may be easier. The uniformly distributed polishing activation solution 142 activates the abrasive on the protrusion portion 134 of the polishing pad 130.

As shown in FIG. 2, the object to be polished 125 is pressed on the polishing pad 130, and the object to be polished 125 and the polishing pad 130 rotate relative to each other S4. Pressing the object to be polished 125 may be performed using a pressing device that is provided in the polishing head 120. The object to be polished 125 and the polishing pad 130 may rotate relative to each other using the rotation of the polishing table 110 and/or the polishing head 120. If the polishing table 110 and the polishing head 120 rotate simultaneously, the directions of rotation may be identical or opposite to each other. If the rotation directions of the polishing table 110 and the polishing head 120 are the same, polishing friction force is not generated if rotation speeds (rotation angular speed) thereof are the same as each other. The rotational speeds may be different from each other. The absolute values of the relative rotation speeds of the polishing table 110 and the polishing head 120 are larger than 0. In order to provide desirable polishing friction force, as shown by the arrows in FIGS. 2 and 5, the rotational directions of the polishing table 110 and the polishing head 120 may be opposite to each other.

Because the polishing activation solution 142 is more uniformly distributed on the polishing pad 130, the abrasive disposed (or positioned) on the protrusion portion 134 of the polishing pad 130 is more uniformly activated. As such, it is possible to perform more uniform polishing and planarization.

Application of the polishing activation solution to which the surfactant is added (S3) and the relative rotation of the object to be polished 125 and the polishing pad 130 (S4) may be performed simultaneously.

The CMP method using the above-mentioned CMP apparatuses 100 and 101 may be used to planarize an isolation region, an interlayer insulating layer, a conductive layer or the like of a semiconductor device such that a pattern is formed.

A method of forming the isolation region of the semiconductor device using the CMP method will be schematically described.

FIGS. 6 to 10 are diagrams illustrating sectional views of the fabrication of the semiconductor device according to example embodiments.

Referring to FIG. 6, a pad oxide layer 210a and a nitride layer 220a for a hard mask may be sequentially formed on a semiconductor substrate 200a. The pad oxide layer 210a may be formed to reduce stress between the semiconductor substrate 200a and the nitride layer 220a. The pad oxide layer may be formed with a thickness of about 20 Å to about 200 Å. The deposition may be performed by using a typical process (e.g., CVD (Chemical Vapor Deposition), SACVD (Sub-Atmospheric CVD), LPCVD (Low Pressure CVD) or PECVD (Plasma Enhanced CVD)).

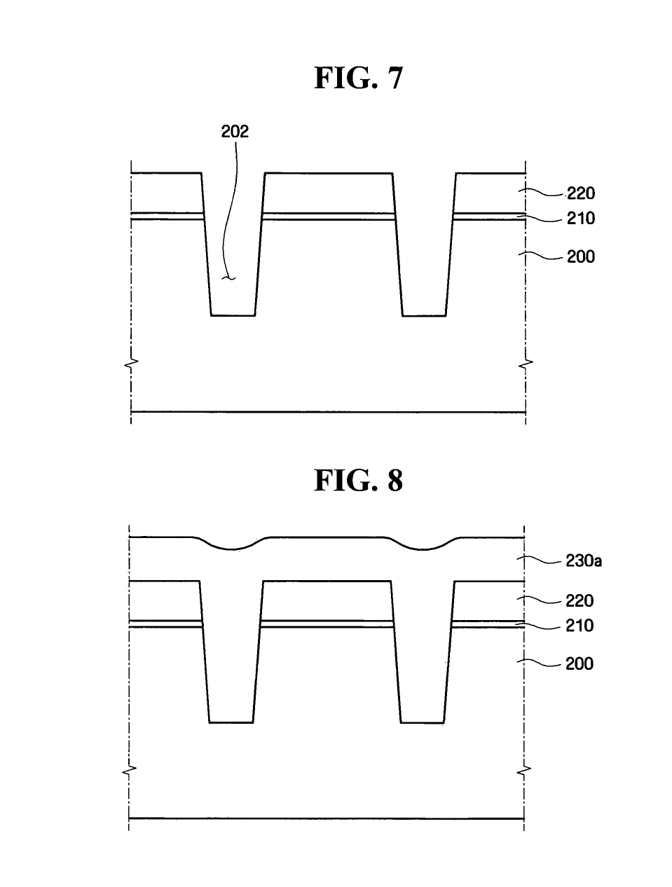

Referring to FIG. 7, an organic ARC (Anti Reflection Coating) (not shown) and a photoresist (not shown) may be selectively applied on the nitride layer 220a. The resulting structure may be exposed and developed to form a photoresist pattern (not shown) that defines an active region. The nitride layer 220a and the pad oxide layer 210a may be etched through a dry etching process using the photoresist pattern (not shown) as a mask to form a nitride layer pattern 220 and a pad oxide layer pattern 210. The nitride layer 220a may be etched using a carbon fluoride gas (e.g., CₓF_{y}-based and CₐH_{b}F_{c}-based gases such as CF₄, CHF₃, C₂F₆, C₄F₈, CH₂F₂, CH₃F, CH₄, C₂H₂, C₄F₆ or combinations thereof) and/or atmospheric gas (e.g., Ar gas).

The photoresist pattern (not shown) may be removed. The exposed semiconductor substrate 200 may be subjected to anisotropic dry etching using the nitride layer pattern 220 and the pad oxide layer pattern 210 as the etching mask to form a Shallow Trench Isolation (STI) trench 202 that defines the active region.

Referring to FIG. 8, an insulating layer 230a for isolating elements may be formed over the STI trench 202. The insulating layer 230a may be an oxide layer (e.g., an HDP oxide layer and a TEOS (tetraethoxysilane) layer). The insulating layer may be deposited (or formed) using a HDP (High Density Plasma) apparatus or a CVD (Chemical Vapor Deposition) apparatus. In order to bury (or fill) the STI trench 202, the insulating layer 230a may be formed to cover an upper surface of the nitride layer pattern 220.

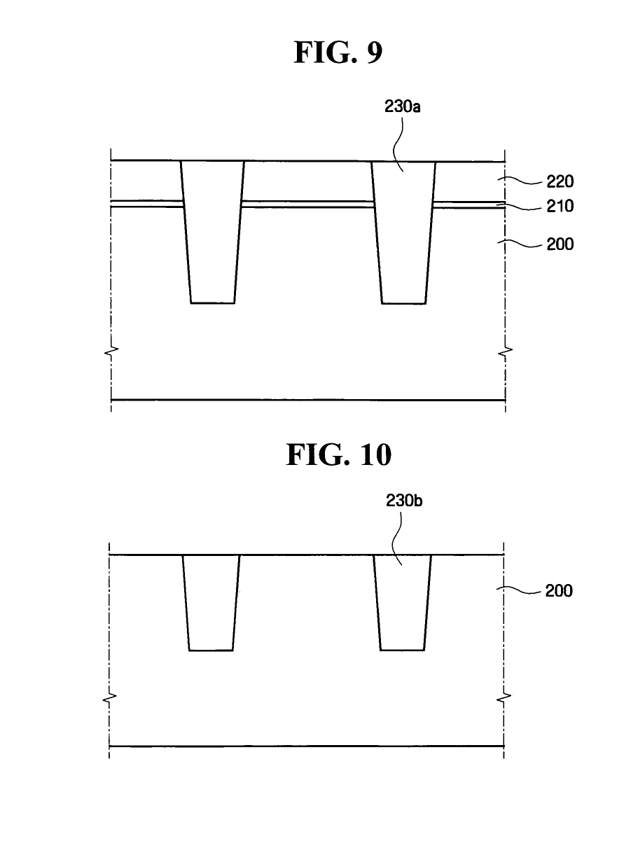

Referring to FIG. 9, the insulating layer 230a may be polished and planarized using the CMP method according to example embodiments described with reference to FIGS. 1 to 5. The nitride layer pattern 220 may be exposed due to the polishing. The nitride layer pattern 220 functions as a CMP stopper with respect to the insulating layer 230a. The abrasive in the polishing pad 130 etches the insulating layer 230a faster than the nitride layer pattern. Because the polishing activation solution includes the surfactant, the surface energy may be low. Because the wetting ability increases and spreading is desirable, the planarization increases. Because the surfactant increases the polishing rate of the insulating layer 230a and the polishing selectivity of the insulating layer 230a to the nitride layer pattern 220, process efficiency increases.

Referring to FIG. 10, the nitride layer pattern 220 and the pad oxide layer pattern 210 may be removed. The nitride layer pattern 220 may be removed using a phosphoric acid. The pad oxide layer pattern 210 may be removed using diluted hydrofluoric acid (HF) or a Buffered Oxide Etchant (BOE) in which NH₄F, HF and deionized water are mixed together. A portion of the upper surface of the insulating layer 230a may be removed. The upper surface of the isolation layer 230b formed may be provided on the upper surface of the semiconductor substrate 200 to be substantially flat.

Although not shown in the drawings, an active element (e.g., a transistor) and a passive element (e.g., a capacitor) maybe formed on an active region defined by the isolation layer using a conventional process. Wires for inputting and outputting electric signals with respect to the active element and the passive element may be formed. A passivation layer may be formed. A detailed description of the subsequent processes incorporated herein will be omitted for the sake of brevity.

### EXPERIMENTAL EXAMPLE 1

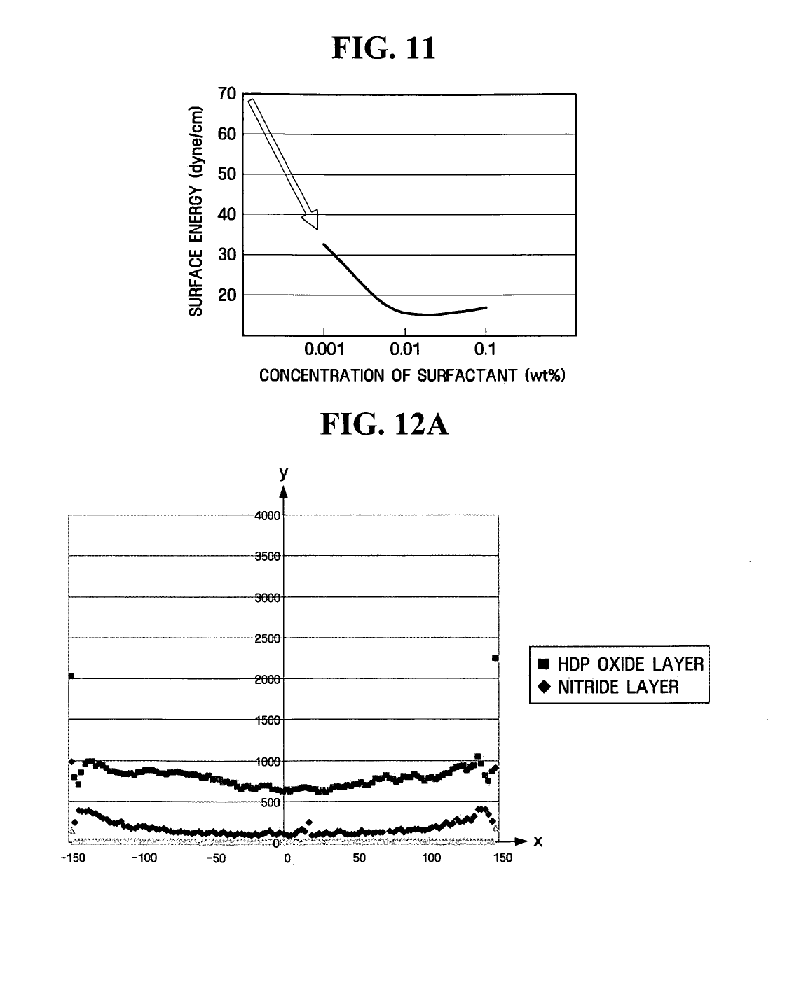

The surface energy of the polishing activation solution was measured while the surfactant was added in small amounts to the polishing activation solution. The results are shown in FIG. 11. FIG. 11 is a graph illustrating the surface energy of the polishing activation solution as a function of an amount of surfactant added according to example embodiments.

Referring to FIG. 11, if the surfactant was not added, the surface energy of the polishing activation solution was about 70 dyne/cm but the surface energy was reduced to 33 dyne/cm to 10 dyne/cm as the amount of surfactant added was gradually increased from 0.001 wt % to 0.1 wt %. If the surfactant is added to the polishing activation solution, the wetting ability increases.

### EXPERIMENTAL EXAMPLE 2

The TEOS layer, the HDP oxide layer and the nitride layer were polished using the CMP apparatus shown in FIG. 2 while the polishing activation solution including 0.1 wt % of the surfactant was supplied to measure the polishing rate.

### COMPARATIVE EXPERIMENTAL EXAMPLE 1

The polishing was performed through the same procedure as Experimental Example 2 to measure the polishing rate except that the polishing activation solution included no surfactants.

The measured polishing rates of Experimental Example 2 and Comparative Experimental Example 1 are shown in the following Table 1.

TABLE 1
(Å/min)

| Comparative | | | Experimental | | |
|---|---|---|---|---|---|
| Experimental Example 1 | | | Example 2 | | |
| TEOS | HDP | Nitride | | HDP oxide | Nitride |
| layer | oxide layer | layer | TEOS layer | layer | layer |
| 184 | 798 | 12 | 519 | 2180 | 8 |

As shown in Table 1, the polishing rates of the TEOS layer and the HDP oxide layer in the case of Experimental Example 2 in which the surfactant is added are higher by about 2.7 times or more than examples where no surfactant was added. The wetting ability of the polishing activation solution increases due to the addition of the surfactant, as shown in Experimental Example 2. The polishing rate of the nitride layer remained substantially constant.

Polishing selectivities with respect to the layers were calculated using the polishing rates of Experimental Example 2 and Comparative Experimental Example 1. The results are shown in the following Table 2.

TABLE 2

| | Comparative | Experimental |
|---|---|---|
| Polishing Selectivity | Experimental Example 1 | Example 2 |
| TEOS layer:nitride layer | 15.1 | 63.3 |
| HDP oxide layer:nitride layer | 65.4 | 265.6 |
| HDP oxide layer:TEOS layer | 4.3 | 4.2 |

As shown in Table 2, the polishing selectivities of the TEOS layer and the HDP layer to the nitride layer are higher in Experimental Example 2.

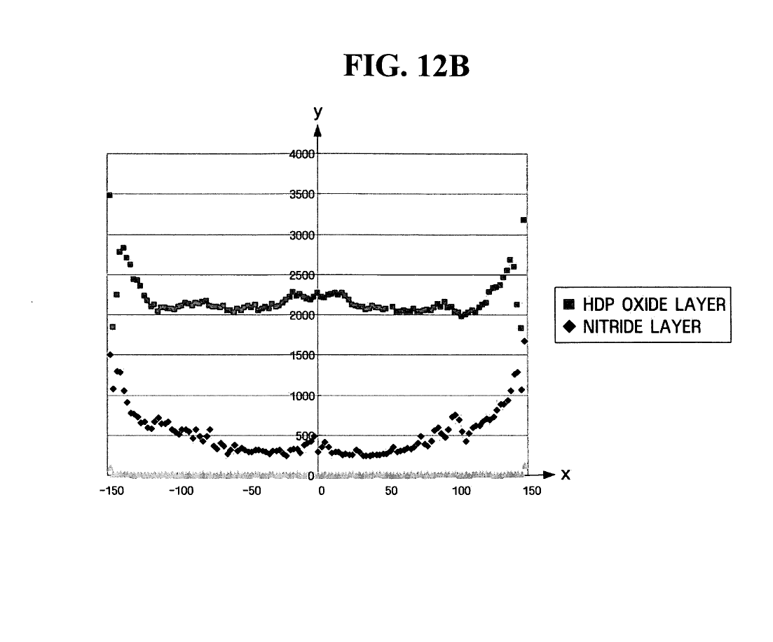

FIG. 12A is a graph illustrating the polishing rates at different positions for a wafer polished using a polishing activation solution including no surfactants. FIG. 12B is a graph illustrating the polishing rates at different positions a wafer polished using the polishing activation solution including the surfactant. In FIGS. 12A and 12B, the distance from the center of the wafer is plotted along the x axis and the polishing rate is plotted along the y axis.

As shown in FIG. 12A, if the wafer is polished using the polishing activation solution including no surfactants, the polishing rate of the HDP oxide layer is substantially lower and the polishing rates are not as uniform on different regions of the wafer. The polishing rate at the center of the wafer is half of the polishing rate at the circumference of the wafer. The polishing uniformity decreases.

As shown in FIG. 12B, if the polishing is performed using the polishing activation solution including the surfactant, the total polishing rate increases and the polishing rates are more uniform throughout the wafer. The pressing device may be disposed (or positioned) in the polishing head of the CMP apparatus to apply different pressures to different regions, more precisely controlling the polishing rate.

In the CMP method according to example embodiments, the wetting ability of the polishing activation solution increases due to the addition of the surfactant, which is added to reduce the surface energy of the polishing activation solution. The polishing efficiency may increase. It may be possible to perform more uniform polishing, increasing the planarization characteristics.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A chemical mechanical polishing process, comprising:
applying a polishing activation solution with a reduce surface energy to an object to be polished, wherein the polishing activation solution includes a surfactant; and
polishing the object using the polishing activation solution.

2. The chemical mechanical polishing process of claim 1, wherein the surfactant is at least one selected from the group consisting of a polymeric anionic fluorinated surfactant, a hydrocarbon surfactant, silicone polyether, sulfosuccinate, aliphatic alcohol and propylated aromatics.

3. The chemical mechanical polishing process of claim 2, wherein polishing of the object includes:
positioning a polishing pad in contact with the object to be polished; and
rotating the object to be polished relative to the polishing pad.

4. The chemical mechanical polishing process of claim 3, wherein the polishing pad includes an abrasive.

5. The chemical mechanical polishing process of claim 4, wherein:
the polishing pad includes a plurality of protrusion portions protruding from an upper surface of the polishing pad; and
the abrasive is attached to a surface of the protrusion portions, provided in the surface of the protrusion portion or buried in the protrusion portion.

6. The chemical mechanical polishing process of claim 5, wherein the plurality of protrusion portions are systematically arranged.

7. The chemical mechanical polishing process of claim 3, wherein the polishing pad includes at least one selected from the group consisting of polyethylene terephthalate (PET), polycarbonate and polyurethane.

8. The chemical mechanical polishing process of claim 3, wherein the surface energy of the polishing activation solution is smaller than or equal to a surface energy of a polishing pad.

9. The chemical mechanical polishing process of claim 1, wherein the surface energy of the polishing activation solution is reduced due to the addition of the surfactant, and the surface energy of the polishing activation solution is about 10 dyne/cm to about 41 dyne/cm.

10. The chemical mechanical polishing process of claim 1, wherein an amount of the surfactant is about 0.0001 wt % to about 1 wt % based on a total weight of the polishing activation solution.

11. A method of fabricating a semiconductor device, the method comprising:
forming a mask layer pattern on a semiconductor substrate;
forming a trench by etching the semiconductor substrate using the mask layer pattern as an etching mask;
forming an insulating layer over the trench; and
performing the chemical mechanical polishing process according to claim 1, wherein the object to be polished is the insulating layer.

12. The method of claim 11, wherein the surfactant is at least one selected from the group consisting of a polymeric anionic fluorinated surfactant, a hydrocarbon surfactant, silicone polyether, sulfosuccinate, aliphatic alcohol and propylated aromatics.

13. The method of claim 12, wherein the polishing of the object includes:
positioning a polishing pad in contact with the object to be polished; and
rotating the object to be polished relative to the polishing pad.

14. The method of claim 13, wherein the polishing pad includes an abrasive.

15. The method of claim 14, wherein:
the polishing pad includes a plurality of protrusion portions protruding from an upper surface of the polishing pad; and
the abrasive is attached to a surface of the protrusion portions, provided in the surface of the protrusion portion or buried in the protrusion portion.

16. The method of claim 15, wherein the plurality of protrusion portions are systematically arranged.

17. The method of claim 13, wherein the polishing pad includes at least one selected from the group consisting of polyethylene terephthalate (PET), polycarbonate and polyurethane.

18. The method of claim 13, wherein the surface energy of the polishing activation solution is smaller than or equal to a surface energy of the polishing pad.

19. The method of claim 11, wherein the surface energy of the polishing activation solution is about 10 dyne/cm to about 41 dyne/cm.

20. The method of claim 11, wherein an amount of the surfactant is about 0.0001 wt % to about 1 wt % based on a total weight of the polishing activation solution.
